(19) United States
(12) Patent Application Publication
(10) Pub. No.: US 2026/0113127 A1
(43) Pub. Date: Apr. 23, 2026

(54) A FREQUENCY MONITORING DEVICE

(71) Applicant: SAAB AB, Linköping (SE)

(72) Inventors: Sten GUNNARSSON, Järfälla (SE); Jan GRABS, Bålsta (SE); Tomas WINDAHL, Trångsund (SE)

(21) Appl. No.: 19/488,254

(22) PCT Filed: Jun. 5, 2024
(86) PCT No.: PCT/SE2024/050553

§ 371 Date: Nov. 26, 2025

(30) Foreign Application Priority Data
Jun. 7, 2023 (SE) 2300053-2

(51) Int. Cl. H04B 17/20

(52) U.S. Cl. CPC H04B 17/202; H03G 3/3042; H03G 3/3052; H04B 1/18; H04B 17/318; H04W 52/52

(57) ABSTRACT

The present disclosure relates to a method (100) for monitoring radio frequency, RF, signals comprising the steps of obtaining (101) an RF signal, the RF signal having an input power. Further, the method comprises extracting (102) a pre-determined portion of said input power to obtain a decoupled RF signal and splitting (103) said decoupled RF signal into a first and a second RF signal. Furthermore, the method comprises altering (104) a frequency response of the second RF signal, determining (105) a power level of the first RF signal and the altered second RF signal and determining (106) a frequency of said RF signal based on a comparison of said power levels of said first RF signal and altered second RF signal.

### TECHNICAL FIELD

The present disclosure relates to a method for monitoring radio frequency signals, a frequency monitoring device and a radio frequency system.

### BACKGROUND

Frequency monitoring (which may also be referred to as spectrum sensing) is a key task in radio frequency systems. The monitoring is usually performed by dedicated modules, typically monitoring a small instantaneous bandwidth with a high sensitivity receiver or a wide instantaneous bandwidth with a less sensitive receiver. In both cases, a priori knowledge about the spectrum is crucial for well performing systems and modules.

This is today sometimes solved by coordinating different sensors on the same platform where e.g. a very wideband receiver gives input to more narrowband systems where specific signals are located. All of these systems do however depend on microwave front-ends sensitive to jamming from strong interfering signals. The existence of a jammer signal might de-sensitive a full radio frequency (RF) system since the receivers need to enter low gain mode to avoid saturation. Furthermore, if the jamming signal is strong enough, the RF front-ends might shut down (in order not to be permanently damaged) resulting in no or reduced RF functionality. Note also that a wideband (e.g. 2-18 GHz) system will shut down over the full bandwidth although the jammer is typically narrowband, occupying nothing but a tiny part of the operational bandwidth.

The frequency monitoring devices of the present art are usually bulky (as they commonly use delay lines) and complex.

There is thus need for frequency monitoring devices which are compact and/or less complex than conventional devices. Preferably, such devices should be compact/less complex while being able to operate over a wide range and withstand high RF power levels while being fast enough to be able to timely adapt RF systems to harming signals.

Hence, it would be desirable to provide a frequency monitoring device that address requirements related to compactness and/or complexity. Preferably, such a frequency monitoring device should also be cheaper compared to conventional frequency monitoring devices while performing in accordance with requirements.

### SUMMARY

It is therefore an object of the present disclosure to alleviate at least some of the mentioned drawbacks to provide an improved frequency monitoring device that is improved at least in terms of compactness/complexity. Further, there is an object of the present disclosure to provide an enhanced method for monitoring RF signals. Additionally, an object of the disclosure is that such a method can be executed within a compact and cost-effective device that performs in accordance with requirements.

This and other objects, which will become apparent in the following, are achieved by a frequency monitoring device and a method for monitoring RF signals as defined in the appended claims.

The present disclosure relates to a method for monitoring radio frequency, RF, signals (preferably RF input signals). The method comprising the steps of obtaining an (input) RF signal, the (input) RF signal having a (input) power. Further, the method comprises the steps of extracting a pre-determined portion of said (input) power to obtain a decoupled RF signal and splitting said decoupled RF signal into a first and a second RF signal. Further, the method comprises the steps of altering a frequency response of the second RF signal and determining a power level of (each of) the first RF signal and the altered second RF signal. Furthermore, the method comprises the step of determining a frequency of said RF signal based on a comparison of said power levels of said first RF signal and altered second RF signal.

The method may in some non-limiting aspects herein be referred to as a method for monitoring RF input signals received at a receiving antenna input of an RF system (e.g., an RF receiving system). Then, the input RF signal is obtained at said antenna input.

An advantage of the method herein is that it allows for a rapid (minimized reaction time being in the range of nanoseconds) and accurate determining of the frequency of an RF signal while having capability to operate over a wide frequency range. The method also is advantageous as, when implemented in a device, it can be designed to be more compact than conventional solutions.

The obtained RF signal may be an unknown signal having an unknown frequency upon being decoupled. Hence, the input signal may be raw. Further, the step of extracting may be performed directly after said input signal is obtained at an antenna input, prior to that said signal has entered a receiver core circuitry.

The step of determining frequency may be performed by determining a difference in RF power between the first RF signal and the altered RF signal. Hence, the term “comparing” may refer to “determining a difference”. The difference may then provide a direct measure of a frequency of the RF signal. By continuous monitoring, the frequency of the dominating RF signal of an RF spectrum may be measured.

The power levels of said first RF signal and altered second RF signal may be determined by a first and a second power detector. The first power detector outputting an output voltage of said first RF signal and the second power detector outputting an output (DC) voltage of said altered second RF signal. The power levels may be determined based on said output voltage.

The power detectors may be diode-based detectors. In some aspects herein, the power detectors are logarithmic power detectors. Preferably, being two identical logarithmic detectors.

An advantage of having two logarithmic power detectors is that it is possible to maintain a constant difference in output signal from the two detectors versus RF power level which enables increased efficiency and reduce complexity when operating the method. In other words, the output signal from these detectors will be linear versus a (input) power measured in dB, and the difference in-between the output of the two detectors will be proportional to the slope of an equalizer/altering device that adjusts frequency response of the second RF signal, thereby facilitating easier frequency extraction in the step of determining frequency of said RF signal. Further, the difference in output signals from the two detectors will be close to independent of RF power levels.

It should be noted that the decoupled signal may be void of any analog to digital transformation/converting.

The method herein may further comprise the step of determining said (input) power (in absolute levels). If said power exceeds a pre-determined power level, the method may further comprise controlling an analog and/or digital circuitry of an RF system to adapt said RF system for a time-period. The adaptation may e.g. be to turn off/deactivate the RF system for a time-period so to prevent the RF system to be affected adversely by a strong jammer. The adaptation may additionally or alternatively comprise filtering out specific frequency components. The power may be determined by a detector device that obtains said first RF signal. Accordingly, the frequency monitoring device herein may be referred to as a frequency and power monitoring device as it may also monitor a power of RF signals. The time-period may be varying based on the power level or any other characteristics of the signal. Hence, the time-period may e.g. start from 0.1 nanoseconds to 0.1 milliseconds or to 0.1 seconds or longer.

In some aspects of the method herein, if the frequency of said RF signal is within a pre-determined frequency range, the method further comprises the step of controlling an analog and/or digital circuitry of a RF system to supress said RF signal or adapt said RF system. The suppression may be performed e.g. by filter devices of said system. Such as bandpass, highpass, lowpass filters or any combination thereof. The adapting may be e.g. to deactivate the RF system for a time-period to prevent the RF system to be harmed by the signal.

In other words, the controlling may therefore comprise filtering out, adjusting a gain of said RF signal or deactivating the RF system. Hence, jammers and/or strong signals may be suppressed/bypassed.

In some aspects, after the method step of splitting, the first and the second RF signal are equal. Equal may refer to that they are equally divided so that the first and the second RF signal comprise common power levels. However, in other aspects the first and the second RF signal are not equally splitted.

Further, in other aspects herein, the pre-determined portion is typically 1/10 to 1/1000 of said power of said RF signal. Hence, the method may advantageously determine frequency of the RF signal by only decoupling a small portion of the power of the full signal.

The present disclosure further discloses a frequency and/or power monitoring device for monitoring RF signals comprising control circuitry. The control circuitry may comprise a signal extraction module, a power splitter module, a first and a second power monitoring module and an equalizer module. The signal extraction module is configured to extract a pre-determined portion of an power of an RF signal to obtain a decoupled RF signal. Further, the power splitter module is configured to split said decoupled RF signal into a first and a second RF signal. Moreover, the equalizer module is configured to alter a frequency response of the second RF signal. Furthermore, the first power detecting module is configured to determine a power level of the first RF signal and the second power monitoring module is configured to determine a power level of said altered second RF signal. The control circuitry is subsequently configured to determine a frequency of said RF signal based on a comparison of said power levels of said first RF signal and altered second RF signal.

An advantage of the frequency monitoring device as disclosed herein is that it is able to be compact, inexpensive and rapid in frequency determination.

The frequency monitoring device may be implemented on a substrate such as a printed circuit board or integrated circuit (IC).

There is further provided a radio frequency system, preferably a radio frequency receiving system comprising, a receiving antenna, a core receiving circuitry and the frequency monitoring device according to any aspect herein. The frequency monitoring device is arranged at a location associated with an input of said receiving antenna (e.g., in a front-end module of said RF system) for monitoring RF input signals received at said receiving antenna. Generally, all terms used in the description are to be interpreted according to their ordinary meaning in the technical field, unless explicitly defined otherwise herein. All references to “a/an/the [element, device, component, means, step, etc.]” are to be interpreted openly as referring to at least one instance of said element, device, component, means, step, etc., unless explicitly stated otherwise.

### BRIEF DESCRIPTION OF THE DRAWINGS

These and other features and advantages of the present disclosure will now be further clarified and described in more detail, with reference to the appended drawings;

FIG. 1 illustrates a frequency monitoring device in accordance with some aspects of the present disclosure;

FIG. 2 schematically illustrates a method in the form of a flowchart in accordance with some aspects of the present disclosure;

FIG. 3 schematically illustrates an RF receiving system 200 in accordance with some aspects of the present disclosure;

FIGS. 4A-4B illustrates a graph for illustrative purposes;

### DETAILED DESCRIPTION

In the following detailed description, some embodiments of the present disclosure will be described. However, it is to be understood that features of the different embodiments are exchangeable between the embodiments and may be combined in different ways, unless anything else is specifically indicated. Even though in the following description, numerous specific details are set forth to provide a more thorough understanding of the present disclosure, it will be apparent to one skilled in the art that the present disclosure may be practiced without these specific details. In other instances, well known constructions or functions are not described in detail, so as not to obscure the present disclosure.

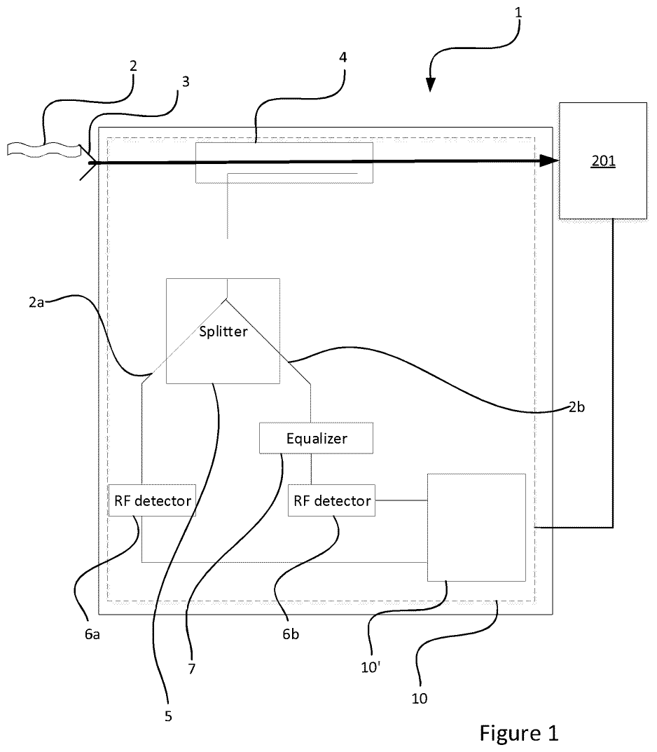

FIG. 1 illustrates, schematically a frequency monitoring device 1 for monitoring RF signals 2 received at a receiving antenna input 3. The device 1 comprising control circuitry 10 comprising a signal extraction module 4, a power splitter module 5, a first and a second power monitoring module 6a, 6b and an equalizer module 7.

The power splitter module 5 may be any suitable power splitter module 5 for splitting an RF signal. The splitter may for example be a Wilkinson power divider. The signal extraction module 4 may comprise any suitable hardware component for extracting a part of said signal 2. A coupler implementation could be used where low loss from RFin to RFout is seeked and when bandwidth is low or moderate. Resistive couplers could be used for small size and ultra-wideband operation. A single component such as a resistor may also be utilized.

The power monitoring modules 6a, 6b may be any suitable power monitoring module 6a, 6b arranged to provide an output voltage based on a signal received therein. The power detectors may comprise diodes.

The equalizer module 7 may be any suitable equalizer module having a pre-determined slope and predetermined loss so to match a desired frequency band of the device 1.

Even though FIG. 1 illustrates that the equalizer module 7 and the second RF detector module are separated. In some aspects they may be a single module. Further, the term module herein may in some aspects of the disclosure be interchanged with unit/device. Some modules herein may be formed as a single module. E.g. the 1^{st} and 2^{nd} power monitoring modules may be one module. Further, the equalizer module may be integrated with said power monitoring modules in some aspects. Accordingly, the specific circuitry of FIG. 1 is non-limiting.

The control circuitry 10 may include a memory device (not shown), an input interface (not shown), at least one output interface (not shown), wherein the control circuitry 10 may be configured to execute instruction sets stored in the memory device. The memory device may comprise any form of volatile or non-volatile computer readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device readable and/or computer-executable memory devices that store information, data, and/or instructions that may be used by each associated control circuitry 10. Each memory device may store any suitable instructions, data or information, including a computer program, software, an application including one or more of logic, rules, code, tables, etc. and/or other instructions capable of being executed by the control circuitry 10 and, utilized. Memory device may be used to store any calculations/control commands made by control circuitry 10 and/or any data received via interface. In some embodiments, each control circuitry 10 and each memory device may be considered to be integrated. The control circuitry 10 may include, for example, one or more central processing units (CPUs), graphics processing units (GPUs) dedicated to performing calculations, modules 4, 5, 6a, 6b, 8 and/or other processing devices. E.g., the memory devices may store any processing performed by the modules 4, 5, 6a, 6b, 8.

The signal extraction module 4 is configured to extract a pre-determined portion of a power of an RF signal 2 to obtain a decoupled RF signal (which may be directly transmitted to the splitter 5. The uncoupled part of the RF signal may then be further transmitted to the RF system core circuitry 201. Hence, the core circuitry 201 may be separate from the control circuitry 10, wherein the control circuitry 10 may control a core circuitry input, so to (at least act to) prevent if said input power exceeds a pre-determined power level, said signal from reaching said core circuitry 201.

Further, the power splitter module 5 is configured to split said decoupled RF signal into a first and a second RF signal 2a, 2b. Further, the equalizer module 7 is configured to alter a frequency response of the second RF signal 2b. In some aspects, both first and second RF signals 2a, 2b may be altered (then by different equalizers having different slopes so that they are altered differently). Hence, in some aspects, at least the second signal is be altered. In some aspects only the second RF signal 2b is altered, while the first frequency response of the first RF signal is undisturbed (i.e. unaltered frequency response of the first RF signal by e.g. an equalizer). The first power detecting module is configured to determine a power level of the first RF signal 2a and the second power monitoring module 6b is configured to determine a power level of said altered second RF signal. The control circuitry 10 is configured to determine a frequency of said input RF signal 2 based on a comparison of said power levels of said first RF signal and altered second RF signal. Further, in some aspects, the control circuitry 10 may be configured to transmit control signals to analog and/or digital circuitry of an RF system based on determined frequency/power levels of signals. The device 1 may be able to determine the frequency/power levels of signals within less than tenths of nanoseconds. Therefore, the control circuitry 10 may be able to transmit control signals/control analog/digital circuitry in the control circuitry, or external of the control circuitry 10, to handle a damaging signal (the uncoupled part) prior to said signal have provided significant/any harm to the RF core circuitry 201.

Specifically, as illustrated in FIG. 1, the control circuitry 10 may comprise a determining module 10′, said determining module being configured to (directly from detectors) receive said first RF signal and the altered second RF signal and determine a frequency of said input RF signal based on a comparison of said power levels of said first RF signal and altered second RF signal.

The determining module 10′ may also determine a power level of signal 2 by receiving an output voltage of said first signal from said first RF detector.

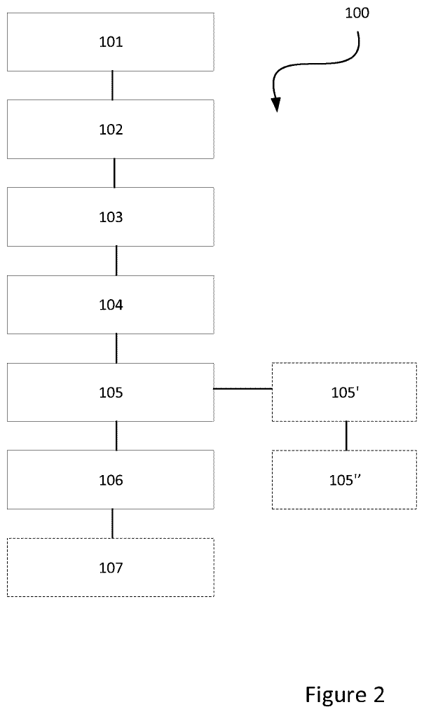

FIG. 2 illustrates a method 100 in the form of a flowchart. Specifically, FIG. 2 illustrates a method 100 for monitoring radio frequency (RF) input signals. Even though FIG. 2 illustrates input signals, the disclosure is not limited to RF input signals, the method may monitor RF output signals also. The method 100 comprises the steps of obtaining 101 an input RF signal, the input RF signal having an input power. Further, the method 100 comprises the steps of extracting 102 a pre-determined portion of said input power to obtain a decoupled RF signal, splitting 103 said decoupled RF signal into a first and a second RF signal. Moreover, the method 100 comprises the step of altering 104 a frequency response of the second RF signal. Furthermore, the method comprises determining 105 a power level of the first RF signal and the altered second RF signal and determining 106 a frequency of said input RF signal based on a comparison of said power levels of said first RF signal and altered second RF signal. The method steps 101-106 (or 101-107) may be performed sequentially without any intermittent steps.

The power levels of said first RF signal and altered second RF signal may be determined by a first and a second power detector, the first power detector outputting an output voltage of said first RF signal and the second power detector outputting an output voltage of said altered second RF signal. Hence, for each signal an output voltage value may be derived. The detectors may be any type of suitable detectors. Preferably, the detectors are logarithmic power detectors.

FIG. 2 further illustrates that the method may further comprise the step of determining 105′ said input power. Hence, the input power of the RF signal (having reference numeral 2 in FIG. 1) may be determined. The full RF signal may be determined by the first RF detector. Further, if said input power of the RF signal exceeds a pre-determined input power level (thereby being defined as a disturbing signal), the method further comprises controlling 105″ an analog and/or digital circuitry of an RF system to adapt said RF system for a time-period.

The time period may be a pre-determined time period. The time-period may be different time periods depending on the system adaptation performed. The time-period may be based on a duration of the disturbing signal.

Further, if said frequency of said input RF signal is within a pre-determined frequency range, the method may further comprise the step of controlling 107 an analog and/or digital circuitry of a RF system to suppress said input RF signal or adapt said RF system. Accordingly, e.g., if the frequency exceeds a specific frequency or is below a specific frequency the analog and/or digital circuitry may be controlled. The controlling may comprise filtering out or adjusting a gain of said input RF signal. Hence, the digital and/or analog circuitry may comprise for instance a filter-bank that can be configured to filter out signals that are determined as being within said frequency range.

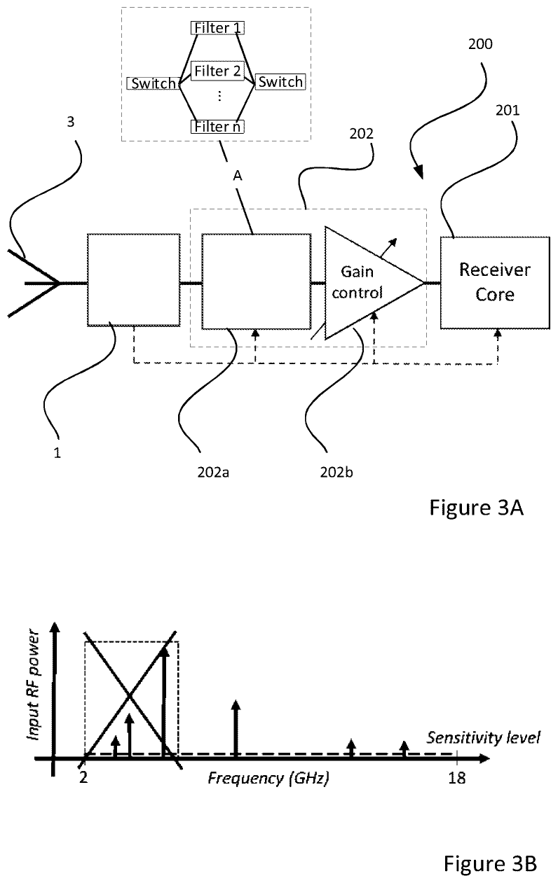

FIG. 3A schematically illustrates an RF receiving system 200 comprising, a receiving antenna 3, a core receiving circuitry 201, a control module 202, the frequency monitoring device 1 according to any aspect herein, wherein said frequency monitoring device 1 is arranged at a location associated with/connected to an input of said receiving antenna 3 for monitoring RF input signals received at said receiving antenna 3. The core receiving circuitry 201 may comprise an oscillator, at least one mixer, up/down-conversion modules, an analog to digital converter, a digital to analog converter, fast Fourier transform modules, amplifiers, filters and other suitable circuitry as appreciated by a skilled person in the art of RF receiving systems.

The receiving antenna 3 may be any suitable type of antenna element and/or antenna array. The control module 202 may comprise switches arranged to switch between parallel filters of a filter bank incorporated therein. By adjusting the number of parallel filters in the filterbank, the full operational receiver bandwidth can be divided into sub-bands and while blocking a sub-band, (substantially) full functionality is obtained in the remaining operation bandwidth of the receiver. Hence, upon detecting an RF signal associated with a pre-determined sub-band, the switch of the module 202 may apply a corresponding filter to filter out said RF signal. An example circuitry implementation of a filter 202a is illustrated by ‘A’ in FIG. 3A

In other aspects the usage of tunable bandstop filters instead of filterbanks may be utilized. Hence, the full operational bandwidth may in aspects herein be covered by a single tunable bandstop filter.

The module 202b illustrates a gain control module 202b arranged to adapt the RF system based on the signal strength. The gain control module 202b may be an automatic gain control module.

The person skilled in the art realizes that the present disclosure by no means is limited to the embodiments described above. The features of the described embodiments may be combined in different ways, and many modifications and variations are possible within the scope of the appended claims. In the claims, any reference signs placed between parentheses shall not be construed as limiting to the claim. The word “comprising” does not exclude the presence of other elements or steps than those listed in the claim. The word “a” or “an” preceding an element does not exclude the presence of a plurality of such elements.

FIG. 3B illustrates a graph showing the performance of the method as disclosed herein after simulations thereof. The purpose of the disclosure of FIG. 3B is to further describe the aspects of the disclosure as presented herein accompanied with advantages thereof. It should be noted that the performance is based on embodiments for a disclosing purpose, however it is not limited to said embodiments and may be varied within the present disclosure.

FIG. 3B illustrates that a jamming signal is filtered out with a minor degradation in sensitivity for the remaining operational bandwidth. The frequency monitoring device automatically switches in one bandstop filter needed to suppress the jammer. Once the jammer is gone, the device will route the incoming RF signal bypassing the filterbank once again.

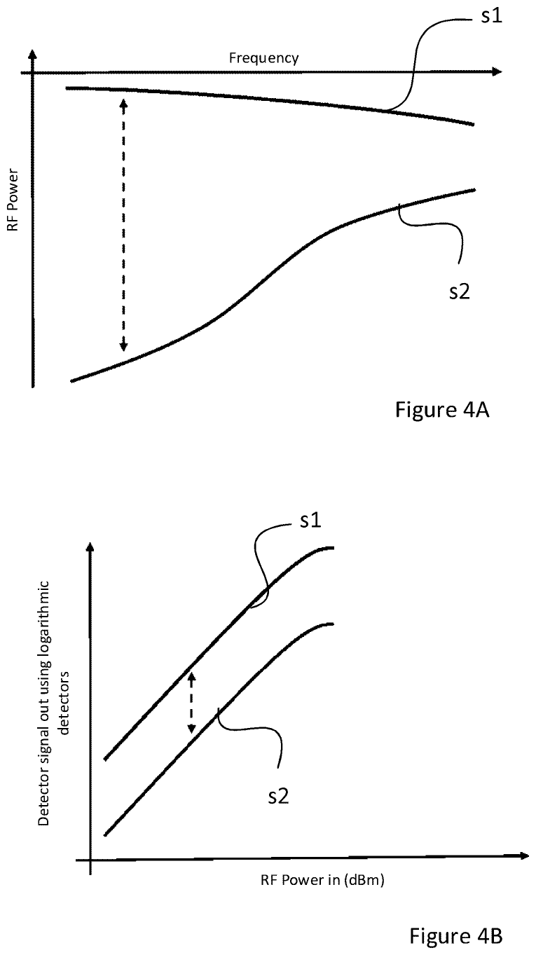

FIG. 4A illustrates a graph in accordance with aspects herein, the graph illustrates that the first signal and the altered second signal s1, s2 (as discussed with reference to FIG. 1) have a difference in RF power levels (which is measured by the power detectors). The difference in power levels can be directly translated to the specific frequency of the dominating input RF signal. The difference may be measured, and the control circuitry may based on the difference determine the frequency of the RF signal (e.g. by calculation or utilizing a LTU (look up table)). In other words, the difference in RF power between s1 and s2 is a direct measure of the frequency of the RF signal. The difference may be measured in said analog and/or digital circuitry.

FIG. 4B illustrates a graph in which logarithmic detectors are utilized. FIG. 4B illustrates that using logarithmic power detectors facilitate more efficient extraction of frequency.

Hence, FIG. 2 illustrates that if both power detectors are identical and of logarithmic type, the output signal from these detectors will be linear versus input power measured in dB and the difference in between the output of the two detectors will be proportional to the slope of the equalizer which facilitates more efficient frequency extraction. Accordingly, for a specific frequency, the difference in output signal from the two power detectors is independent of RF power level.

1. A method (100) for monitoring radio frequency, RF, signals comprising the steps of:
obtaining (101) an RF signal, the RF signal having an input power;
extracting (102) a pre-determined portion of said input power to obtain a decoupled RF signal;
splitting (103) said decoupled RF signal into a first and a second RF signal;
altering (104) a frequency response of the second RF signal;
determining (105) a power level of the first RF signal and the altered second RF signal;
determining (106) a frequency of said RF signal based on a comparison of said power levels of said first RF signal and altered second RF signal.

2. The method (100) according to claim 1, wherein said power levels of said first RF signal and altered second RF signal are determined by a first and a second power detector, the first power detector outputting an output voltage of said first RF signal and the second power detector outputting an output voltage of said altered second RF signal.

3. The method (100) according to claim 2, wherein the power detectors are logarithmic power detectors.

4. The method (100) according to claim 1, further comprising:
determining (105′) said input power;
wherein if said input power exceeds a pre-determined power level, the method further comprises:
controlling (105″) an analog and/or digital circuitry of an RF system to adapt said RF system for a time-period.

5. The method (100) according to claim 1, wherein if said frequency of said RF signal is within a pre-determined frequency range, the method further comprises the step of:
controlling (107) an analog and/or digital circuitry of a RF system to supress said RF signal or adapt said RF system.

6. The method (100) according to claim 5, wherein the controlling comprises:
filtering out or adjusting a gain of said RF signal.

7. The method (100) according to claim 1, wherein, after the step of splitting, the first and the second RF signal are equal.

8. The method (100) according to claim 1, wherein said pre-determined portion is typically 1/10 to 1/1000 of said input power of said RF signal.

9. A frequency monitoring device (1) for monitoring RF signals (2) received at a receiving antenna input (3) comprising control circuitry (10) configured to:
extract a pre-determined portion of an input power of an RF signal (2) to obtain a decoupled RF signal;
split said decoupled RF signal into a first and a second RF signal (2a, 2b);
alter a frequency response of the second RF signal (2b);
determine a power level of the first RF signal (2a);
determine a power level of said altered second RF signal;
wherein said control circuitry (10) is further configured to:
determine a frequency of said RF signal (2) based on a comparison of said power levels of said first RF signal and altered second RF signal.

10. An RF system (200) comprising:
a receiving antenna (3);
a core receiving circuitry (201);
a control module (202);
the frequency monitoring device (1) according to claim 9;
wherein said frequency monitoring device (1) is arranged at a location associated with an input of said receiving antenna (3) for monitoring RF input signals received at said receiving antenna (3).
